(19) United States
(12) Patent Application Publication
(10) Pub. No.: US 2026/0093867 A1
(43) Pub. Date: Apr. 2, 2026

(54) PREDICTION OF CELL POPULATION SIZE, FRACTION, AND RATIOS BY MACHINE LEARNING METHODS ON FLOW CYTOMETRY DATA

(71) Applicant: UNIVERSITY OF UTAH RESEARCH FOUNDATION, Salt Lake City, UT (US)

(72) Inventor: David P. Ng, Salt Lake City, UT (US)

(21) Appl. No.: 19/347,063

(22) Filed: Oct. 1, 2025

Related U.S. Application Data
(60) Provisional application No. 63/702,524, filed on Oct. 2, 2024.
(60) Provisional application No. 63/702,501, filed on Oct. 2, 2024.

(51) Int. Cl. G06F 30/20

(52) U.S. Cl. CPC G06F 30/20

(57) ABSTRACT

Systems, methods, and apparatuses for performing real-time cytometry data analysis. One apparatus includes at least one electronic processor and at least one memory storing instructions executable by the at least one electronic processor. The at least one electronic processor is configured, through execution of the instructions, to obtain flow cytometry data generated by a cytometry instrument representing cells of multiple categories, generate a feature vector representation based on the flow cytometry data using a plurality of self-organizing maps (SOMs), wherein each SOM corresponds to a different category of multiple categories, and predict each of one or more target labels of the cells by applying each of one or more regression models to the feature vector representation.

### RELATED APPLICATIONS

This application claims priority to U.S. Provisional Application Nos. 63/702,524 and 63/702,501, both filed Oct. 2, 2024, the entire content of each is incorporated by reference herein.

### FIELD

Examples described herein generally relate to flow cytometry and, in particular, processing flow cytometry data.

### SUMMARY

Flow cytometry is a technique used in biology, immunology, and medical diagnostics to analyze physical and chemical characteristics of individual cells or particles in a fluid stream. Gating in flow cytometry analysis involves identifying and isolating specific cell populations of interest based on measured characteristics. Gating allows researchers and clinicians to quantify specific cell populations, facilitating the understanding of cellular systems and diagnosing various conditions.

Some gating methods rely on manual interpretation of two-dimensional scatter plots, where human analysts draw boundaries (gates) around a cell population of interest. These manual gating methods, while widely used, are time-consuming, subjective, and prone to variations of interpretations across different observers. For example, manual gating may lead to inconsistencies in results across different analysts or laboratories.

Some automated gating methods are developed to address subjective and inter-observer variability. However, these automated gating algorithms struggle with complex or overlapping cell populations. Moreover, both the manual gating and the automated gating methods are less effective when dealing with high-dimensional data from modern flow cytometers, which can measure, for example, dozens of parameters simultaneously.

Aspects of the present disclosure provide an approach to flow cytometry data analysis that addresses these limitations. By combining self-organizing maps (SOMs) for feature extraction with machine learning regression models for classification, and utilizing clinically validated data for providing target variables, the approach enables the prediction cell population characteristics within a fluid comprising multiple cell populations, bypassing the gating of specific cell populations.

In some examples, the systems and methods described herein transform raw flow cytometry data into a standardized, lower-dimensional representation that preserves characteristic information about cell populations. The systems and methods use this representation to directly predict cell population characteristics, such as, for example, percentages of different cell types or expression levels of specific markers. This approach reduces subjectivity and inter-observer variability, while also handling complex and overlapping populations more effectively. In some examples, this approach also scales well to high-dimensional data and decreases analysis time.

In some examples, by training on clinically validated data, aspects of the present disclosure provide a flow cytometry analysis system, apparatus, or machine learning model that incorporates expert knowledge while maintaining consistency across analyses. The methods, systems, and apparatuses provided herein thus improve the accuracy, efficiency, and reproducibility of flow cytometry data analysis in research and clinical settings.

In other words, manual gating is laborious and prone to inter-observer variability. Current automated gating solutions have issues with discriminating populations when there are too few events or if there is no clear saddle between populations to optimize a gate. Methods and systems described herein project the data into a latent space using self-organizing maps (SOMs) that describe events in a file and then applies regression predictors to determine the absolute size or the fraction of cells (%) or the ratio between populations sizes given clinical annotations without the need to manually gate or gate or cluster in a bivariate plot.

Methods provided herein avoid the bias caused by manual interpretation as well as issues in gating continuous populations by training the regression predictors (including but not limited to linear regressors to random forest regressors depending on the use case) against a standard of clinically resulted values that are expertly reviewed and adjusted.

While some flow cytometry data systems generate bivariate gates based on the density of populations, these methods work well when the populations are clearly delineated. However, when the population separation is poor (either due to preanalytical issues or biological changes associated with disease or mutation), manual intervention is required.

To address these and other issues, examples described herein provide methods, systems, and apparatuses for performing cytometry data analysis (e.g., real-time data analytics). One apparatus includes at least one electronic processor, and at least one memory storing instructions executable by the at least one electronic processor. The at least one electronic processor is configured, through execution of the instructions, to obtain flow cytometry data generated by a cytometry instrument representing cells of multiple categories, generate a feature vector representation based on the flow cytometry data using a plurality of self-organizing maps (SOMs), wherein each SOM corresponds to a different category of multiple categories, and predict each of one or more target labels of the cells by applying each of one or more regression models to the feature vector representation.

Another example provides a computer-implemented method for analyzing flow cytometry data using machine learning comprising. The method includes obtaining the flow cytometry data generated by a cytometry instrument representing cells of multiple categories, generating a feature vector representation based on the flow cytometry data using a plurality of self-organizing maps (SOMs), wherein each SOM corresponds to a different category of the multiple categories, and predicting, using a machine learning model, each of one or more target labels of the cells by applying each of one or more regression models to the feature vector representation.

Accordingly, the methods, systems, and apparatuses provided herein decrease labor costs in analyzing flow cytometry data while avoiding the performance issues associated with automatic gating techniques.

### BRIEF DESCRIPTION OF THE FIGURES

FIG. 1 schematically illustrates a cytometry data analysis system according to some examples.

FIG. 2 schematically illustrates a real-time data analytics apparatus included in the cytometry data analysis system of FIG. 1 according to some examples.

FIG. 3 is a flowchart illustrating a computer-implemented flow cytometry data analysis method implemented via the data analytics apparatus of FIG. 2 according to some examples.

FIG. 4 is a flowchart illustrating a computer-implemented method for training a machine learning model implemented via the data analytics apparatus of FIG. 2 according to some examples.

FIG. 5 illustrates data processing steps performed via the cytometry data analysis system of FIG. 1 according to some examples.

### DETAILED DESCRIPTION

One or more examples are described and illustrated in the following description and accompanying drawings. These examples are not limited to the specific details provided herein and may be modified in various ways. Furthermore, other examples may exist that are not described herein. Also, the functionality described herein as being performed by one component may be performed by multiple components in a distributed manner. Likewise, functionality performed by multiple components may be consolidated and performed by a single component. Similarly, a component described as performing particular functionality may also perform additional functionality not described herein. For example, a device or structure that is “configured” in a certain way is configured in at least that way but may also be configured in ways that are not listed.

Furthermore, some examples described herein may include one or more electronic processors configured to perform the described functionality by executing instructions stored in non-transitory, computer-readable medium (e.g., to perform the computer-implemented methods described herein). Similarly, examples described herein may be implemented as non-transitory, computer-readable medium storing instructions executable by one or more electronic processors to perform the described functionality. As used in the present application, “non-transitory computer-readable medium” comprises all computer-readable media but does not consist of a transitory, propagating signal. Accordingly, non-transitory computer readable medium may include, for example, a hard disk, a CD-ROM, an optical storage device, a magnetic storage device, a ROM (Read Only Memory), a RAM (Random Access Memory), register memory, a processor cache, or any combination thereof.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

Also, it should be understood that the illustrated components, unless explicitly described to the contrary, may be combined or divided into separate software, firmware and/or hardware. For example, as noted above, instead of being located within and performed by a single electronic processor, logic and processing described herein may be distributed among multiple electronic processors. Similarly, one or more memory modules and communication channels or networks may be used even if examples described or illustrated herein have a single such device or element. Also, regardless of how they are combined or divided, hardware and software components may be located on the same computing device or may be distributed among multiple different devices. Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

In addition, the phraseology and terminology used herein is for the purpose of description and should not be regarded as limiting. For example, the use of “including,” “containing,” “comprising,” “having,” and variations thereof herein is meant to encompass the items listed thereafter and equivalents thereof as well as additional items. The terms “connected” and “coupled” are used broadly and encompass both direct and indirect connecting and coupling. Further, “connected” and “coupled” are not restricted to physical or mechanical connections or couplings and can include electrical connections or couplings, whether direct or indirect. In addition, electronic communications and notifications may be performed using wired connections, wireless connections, or a combination thereof and may be transmitted directly or through one or more intermediary devices over various types of networks, communication channels, and connections. Moreover, relational terms, such as, for example, first and second, top and bottom, and the like may be used herein solely to distinguish one entity or action from another entity or action without necessarily requiring or implying any actual such relationship or order between such entities or actions.

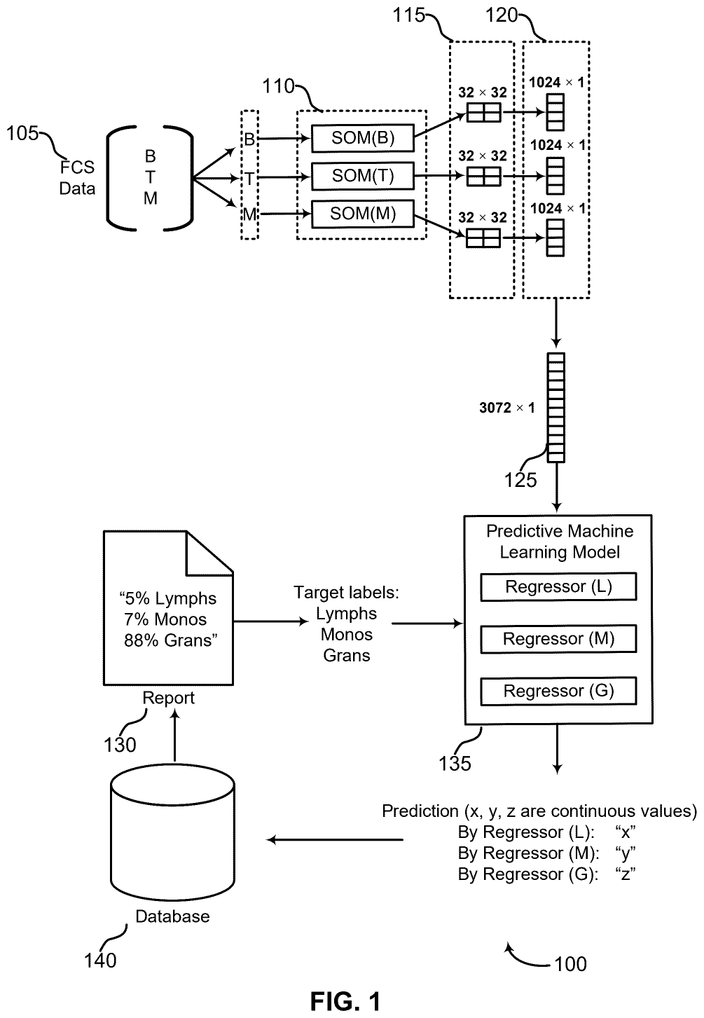

FIG. 1 schematically illustrates a cytometry data analysis system 100. The system 100 receives, as input, Flow Cytometry Standard (FCS) data 105, which contains detailed information about cellular characteristics from the cytometry instrument. The FCS data 105 may be obtained or generated based on raw data generated by one or more cytometers. For example, the FCS data 105 may comprise measurements for B (B lymphocytes), T (T lymphocytes), and M (Myeloid). However, examples of the present disclosure may not be limited thereto as the FCS data 105 may comprise measurements for panel types other than B, T, or M.

A cytometer generally refers to an analytical instrument used to analyze physical and chemical characteristics of individual cells or particles in a fluid stream. The cytometer comprises components, such as, for example, (i) a fluidics system that transports and aligns cells in a single file through a laser beam, (ii) one or more lasers for illumination, (iii) a series of optical filters and mirrors to direct specific wavelengths of scattered and fluorescent light, (iv) multiple photodetectors, such as, for example, photomultiplier tubes to capture and quantify the light signals, and (v) a computer system for data acquisition and analysis. For example, as cells pass though the laser beam, the cytometer (e.g., the computer system processing data captured via the photodetector(s)) measures forward scatter, side scatter, and fluorescence emissions from labeled cellular components. The cytometer as described herein may be used to perform flow cytometry, mass cytometry, or imaging cytometer and may include various types of detectors. For example, in addition or in place of the photodetectors noted above, the cytometer may include one or more Photomultiplier Tubes (PMTs), Avalanche Photodiodes (APDs), Complementary Metal Oxide Semiconductor (CMOs), Charged Coupled Devices (CCDs), or a combination thereof. In some examples, the functionality and methods described herein may be performed via the computer system of the cytometer, via one or more computer systems external to the cytometer, or a combination thereof.

As illustrated in FIG. 1, the FCS data 105 is processed through multiple Self-Organizing Maps (SOMs) 110, with each SOM corresponding to a different cell type or category. The SOMs 110 transform the high-dimensional cytometry data 105 into more manageable representations. In some examples, I output of each SOM 110 is a 32×32 representation 115 of the data for its corresponding cell type.

Each SOM 110 may include a neural network trained using an unsupervised machine learning technique that reduces complex, high-dimensional data into a low-dimensional (e.g., two-dimensional) grid, preserving the topological structure of the input data. The SOM 110 uses a competitive learning approach to cluster similar data points together on the grid (also referred to as a map). The neural network begins with a random set of weights for its nodes, representing points in the input space. For each input data point, the neural network finds the “Best Matching Unit” (BMU), which is the node whose weights are closest to the input data. The weights of the BMU are adjusted to become more like the input data. The weight of one or more nodes neighboring the BMU are also adjusted, but to a lesser extent than the adjustment to the BMU weights. This process is repeated for multiple input data points, gradually shaping the map so that similar data point cluster together on the map.

Next, for example, each 32×32 representation 115 is converted into a 1-dimensional representation 120. However, the examples of the present disclosure may not be limited thereto, and the representation may be of size N×N, where N is a natural number greater than 1. This transformation further simplifies the data structure while retaining essential information about the cell populations. These 1-dimensional representations are then concatenated to form a single, comprehensive concatenated representation 125. This step combines the information from the different cell types into a unified feature vector (e.g., a 3072×1 representation).

In some examples, the concatenated representation is used as input to a predictive machine learning model 135. This model consists of multiple regressors (L, M, G) that operate on the same input data to predict different target variables (x, y, z). For example, the target variables may represent percentages of different cell types or other clinically relevant metrics. The predictions generated by the machine learning model 135 may be stored in a database 140. The database 140 may be a repository for the analysis results and allows for easy retrieval and comparison of data over time. In some examples, clinically validated data is stored in the database 140. In some examples, the target variables include various lymphocyte subsets, precursor cells (blasts), and cellular viability.

Subsequently, a report 130 (e.g., a digital report 130) can be generated from the data stored in the database 140, providing a clear and concise summary of the predicted target variables (x, y, z). For example, the report 130 may offer a user-friendly way to interpret the results of the flow cytometry analysis, facilitating researchers or clinicians to draw insights from the data. In some examples, the report 130 is generated based on clinically validated data and the predicted target variables. In some examples, the report 130 is represented as a user interface (accessible for display on a display device of a user computing device), where one or more data fields of the user interface are populated based on data stored in the database 140.

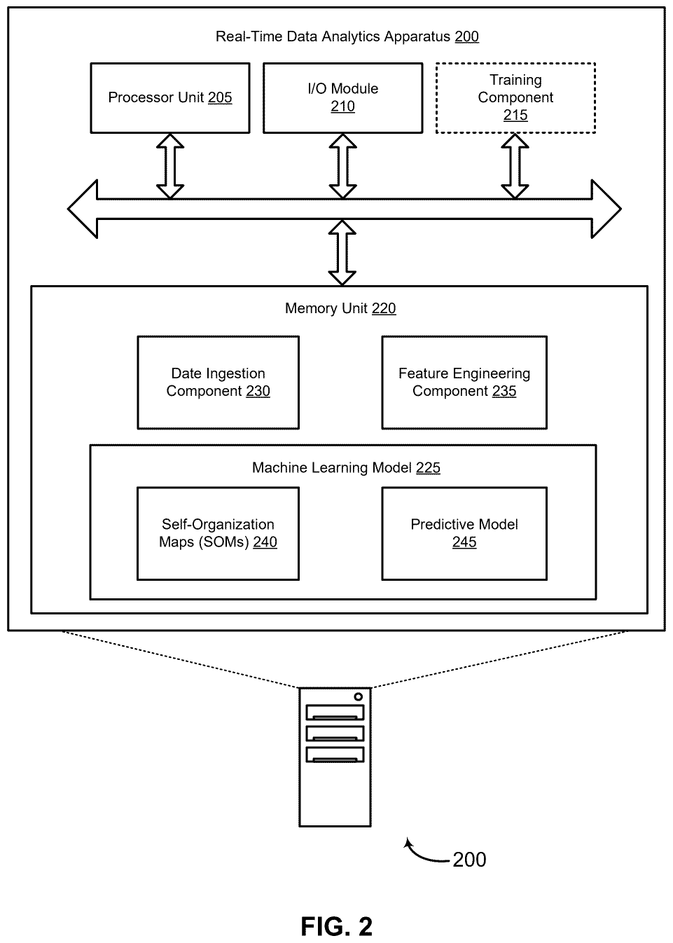

FIG. 2 schematically illustrates a real-time data analytics apparatus 200 included in the cytometry data analysis system 100, which may be used to implement the functionality describe herein as being performed via the cytometry data analysis system 100. Real-time data analytics apparatus 200 includes a processor unit 205 (such as, for example, one or more electronic processors), an input/output (I/O) module 210, an optional training component 215, and a memory unit 220. The memory unit 220 includes a data ingestion component 230, a feature engineering component 235, and a machine learning model 225 comprising SOMs 240 and a predictive model 245. It should be understood that the apparatus 200 may include additional or fewer components and the components illustrated in FIG. 2 may be combined and distributed in various configurations. For example, the apparatus 200 may include more than one processor unit 205, more than one I/O module 210, more than one training component 215, more than one memory unit 220, or a combination thereof. Also, the functionality described herein as being performed via the components stored in the memory unit 220 may be combined and distributed in additional or fewer components, wherein a component may include a set of instructions (software) and/or data executable by the processor unit 205. It should also be understood that the functionality described herein as being performed via the apparatus 200 may be distributed among multiple devices.

As noted above, the processor unit 205 may include a microprocessor, an application-specific integrated circuit, or the like. The memory unit 220 includes non-transitory, computer-readable memory. The I/O module 210 includes one or more an input/output interfaces for communicating with components external to the apparatus 200 over one or more wired or wireless communication channels or networks.

As described herein, the optional training component 215, which may be implemented as software stored in the memory unit 220 or stored in a separate memory unit of the apparatus 200, is configured to train the models and/or neural network included in the machine learning model 225 (e.g., the SOMs 240 and/or the predictive model 245). In particular, the training component 215 may be configured to initialize the models/networks, iteratively input training data (which may be stored in the training component 215 or elsewhere) to the models/networks, and adjust internal parameters (e.g., weights and biases) of the models/networks until the models/networks is considered trained or accurate (e.g., until a loss function is minimized). The training component 215 is illustrated as being optional as, in some examples, the models/networks included in the machine learning model 225 may be initially trained by a separate apparatus as the apparatus 200 performing the real-time data analysis.

As used herein, “real-time” refers to a system or process that responds and updates immediately or with minimal delay, typically within milliseconds or microseconds. This immediacy allows information to be accessed and acted upon almost instantaneously. As used herein, “real-time” also includes “near real-time,” which implies a slight but acceptable delay in data processing and response, such as within seconds or a few minutes. Accordingly, real-time can be contrasted with “batch processing” or “offline processing,” wherein data is collected, stored, and processed at a later time. In some examples, the data ingestion component 230 is configured to obtain and preprocess flow cytometry data generated by a cytometry instrument. For example, data ingestion component 230 may be configured to handle the Flow Cytometry Standard (FCS) data 105 representing cells of multiple categories or types. The data ingestion component 230 prepares the raw data for further analysis by making the preprocessed data in a suitable format for the subsequent processing steps.

In some examples, the feature engineering component 235 is configured to generate a feature vector representation based on the flow cytometry data 105. The feature engineering component 235 may work in conjunction with the Self-Organizing Maps (SOMs) 240 (which may include the SOMs 110 described above with respect to FIG. 1) to transform the high-dimensional cytometry data into a more manageable and informative representation.

In some examples, the Self-Organizing Maps (SOMs) 240 are configured to process the flow cytometry data 105 for different cell categories. Each SOM 240 corresponds to a different category of cells and is responsible for creating a lower-dimensional representation of the data for its specific cell type.

In some examples, the predictive model 245 (which may include the predictive machine learning model 135 described above with respect to FIG. 1) may be configured to predict one or more target labels of the cells by applying one or more regression models to the feature vector representation generated by the feature engineering component 235 and SOMs 240. The predictive model 245 may include one or more types of regression models, such as, for example, linear regressors or random forest regressors. The predictive model 245 is configured to output predictions for various cell characteristics such as, for example, absolute cell size, fraction of cells of a particular type, or ratios between different cell population sizes.

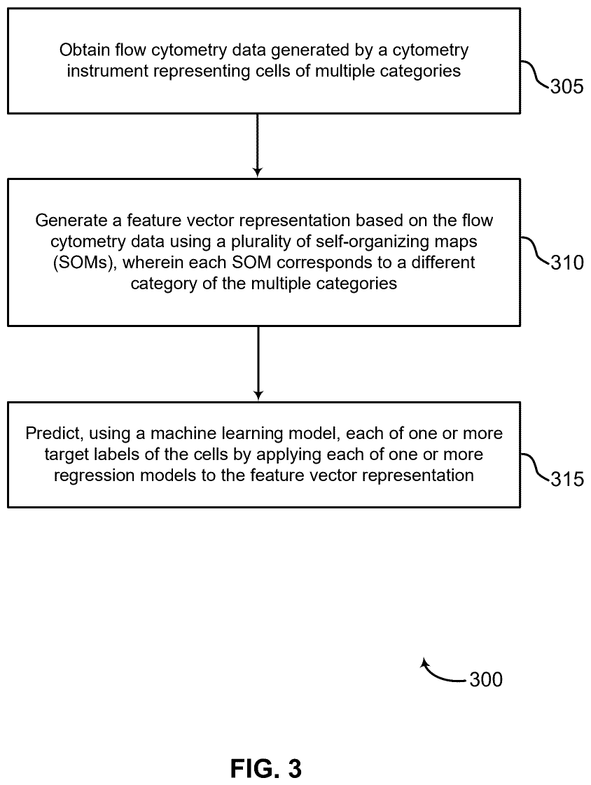

FIG. 3 is a flowchart illustrating a computer-implemented a flow cytometry data analysis method 300. The method 300 may be performed by a computer system, such as, for example, the real-time data analytics apparatus 200 illustrated in FIG. 2 to implement the functionality of the system 100 described herein.

At operation 305, the computer system obtains the flow cytometry data generated by a cytometry instrument representing cells of multiple categories. In some examples, the data comes in the form of Flow Cytometry Standard (FCS) data 105, with each category representing a different cell type. The data contains information about various cellular characteristics measured by the cytometry instrument for a large number of individual cells.

At operation 310, the computer system generates a feature vector representation based on the flow cytometry data using a plurality of self-organizing maps (SOMs) 240, wherein each SOM corresponds to a different category of the multiple categories. In some examples, the computer system applies each SOM 240 to the flow cytometry data 105 representing cells of its corresponding category. This operation 310 generates a plurality of latent representations 115, each capturing the key features of a specific cell type. Next, the computer system converts each of these latent representations 115 into a one-dimensional vector representation 120. This operation 310 transforms the complex, multi-dimensional data from each SOM 240 into a more manageable format. Subsequently, the computer system concatenates these one-dimensional vector representations 120 to generate the overall feature vector representation 125. This concatenation combines the information from the different cell types into a single, comprehensive vector 125.

At operation 315, the computer system predicts, using the machine learning model 135 (i.e., the predictive model 245), each of one or more target labels of the cells by applying each of one or more regression models to the feature vector representation 120. The target labels may include absolute cell size, fraction of cells of a particular type, or ratios between different cell population sizes. The regression models used for prediction may include linear regressors, random forest regressors, or other suitable machine learning models.

In some examples, the regression models are trained on clinically validated data. The predictions made by the regression models may thus align with expert-verified results. In some examples, the computer system uses different types of regression models depending on the specific target label being predicted. After making the predictions, the system may update a dataset with the predicted target labels, allowing for continuous improvement and validation of the model's performance. Accordingly, the portion of the method 300 comprising operations 305, 310, and 315 allows for automated and consistent analysis of flow cytometry data without gating, addressing challenges associated with some manual and automated flow cytometry analysis methods.

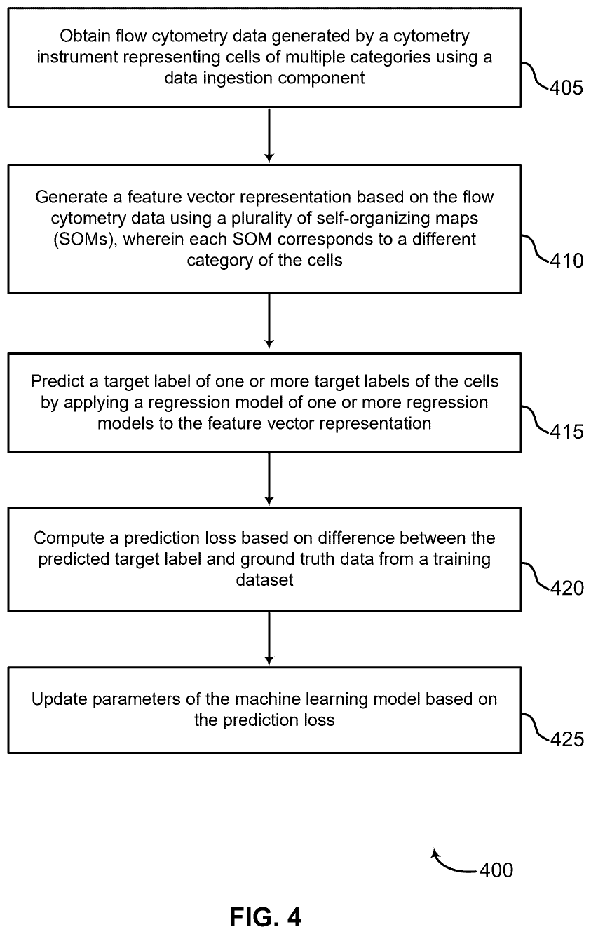

FIG. 4 is a flowchart illustrating a computer-implemented method 400 for training a machine learning model (e.g., the predictive mode 245) used for the cytometry analysis performed as part of the method 300. The method 400 may be performed by a computer system, such as, for example, the real-time data analytics apparatus 200 in FIG. 2. However, in other configurations, the method 400 may be performed by an apparatus separate from the apparatus 200, wherein the trained model is transferred and stored on the apparatus 200 for inference use. The method 400 for training the model may be implemented by a training components, such as, for example, the optional training component 215 illustrated in FIG. 2.

At operation 405, the computer system obtains flow cytometry data generated by a cytometry instrument representing cells of multiple categories using a data ingestion component. This typically involves acquiring Flow Cytometry Standard (FCS) data, where each category represents a different cell type. The data ingestion component processes and prepares the raw cytometry data for further analysis.

At operation 410, the computer system generates a feature vector representation based on the flow cytometry data using a plurality of self-organizing maps (SOMs) 240, wherein each SOM 240 corresponds to a different category of the cells. In some examples, operation 410 involves generating a plurality of latent representations 115 by applying each SOM 240 to flow cytometry data representing cells of its corresponding category. Next, the computer system converts each of these latent representations 115 into a one-dimensional vector representation 120, forming a set of one-dimensional vector representations 120. Subsequently, the computer system concatenates these one-dimensional vector representations 120 to generate the overall feature vector representation 125.

At operation 415, the computer system predicts a target label of one or more target labels of the cells by applying a regression model of one or more regression models to the feature vector representation 125 (i.e., models included in the predictive machine learning model 135). The regression models can include linear regressors, random forest regressors, or other suitable types. The target labels may include absolute cell size, fraction of cells of a particular type, or ratios between different cell population sizes.

At operation 420, the computer system computes a prediction loss based on the difference between the predicted target label and ground truth data (included as part of the training data obtained at operation 405). This operation 420 quantifies how well the model's predictions align with the known, validated data in the training set.

At operation 425, the computer system updates parameters of the machine learning model 135 (i.e., parameters of the one or more regressors) based on the prediction loss. For example, at operation 425, the computer system may use the training component 215 to adjust parameters of a predictive model 13 to improve the predictive accuracy based on the computed loss. In some examples, the training process 400 may be repeated for flow cytometry data until the prediction loss is minimized. The repetition gradually improves the model's ability to accurately make predictions. Once trained, the trained machine learning model 135 is used part of the analysis system 100 described herein. In some examples, after these operations, the computer system may update the training dataset (included in a database 140 in FIG. 1) with the predicted target labels, allowing for continuous refinement of the model 135.

### Use Case Example

As noted above, the methods and systems described herein can be used to perform various types of analytics. For example, the methods and systems may be used to predict which samples from a Leukemia/Lymphoma phenotyping flow cytometry assay have no clinically significant findings. Samples in the above-noted assay currently undergo a manual review process involving differentiation of cell populations using hand-drawn polygons (“gates”). The manual gating process is time consuming and can lead to inter-pathologist variability in findings. Additionally, approximately half of all cases receive a “normal” diagnosis, indicating no significant clinical findings.

Accordingly, applying the methods and systems described herein to the sample of this type of assay generates predictions for when a sample is likely to receive a normal diagnosis, which addresses, among other things, the above issues associated with manual gating and review and results in greater laboratory efficiency and more reproducible results.

Specifically, the predictive model 245 described herein may be trained to detect peripheral blood samples with no signs of disease or sample quality issues from the flow cytometer outputs for the B-Cell, T-Cell, and Myeloid tubes (referred to as herein as “normal” samples). When the predictive model 245 predicts a sample is normal with high confidence, user-interface elements of a web-based reporting system pre-populates the report text field with standard text indicating no reportable findings and routes the results to a pathologist for final review. Thus, the predictive model and associated analytic system reduces the manual review and report generation process for laboratory staff with normal samples and improves test Turn-Around-Time (TAT), since normal samples may comprise about half of the testing volume.

The methods and systems described herein may similarly be used to determine sample cell viability. Low cell viability can be an indicator of poor sample quality and may require full analyst evaluation for report generation or sample rejection and rerun. For example, some current guidelines indicate that viability in such situations must be greater than 80%, and, as this viability is currently assessed by a manual event gating procedure, the methods and systems described herein can be used to estimate viability, which can support an acceptance of a normal diagnosis as well as simplify report generation and avoid inefficiencies associated with manual evaluations and potential reruns.

In this use case, “normal” means a case without any diagnosis or quality issue, “positive” means a case with a prediction score greater than a predetermined threshold, and “negative” means a case with a prediction score less than a predetermined threshold. Similarly, a “false positive” is a case that is incorrectly called normal, a “false negative” is a case that is incorrectly called abnormal, a “true negative” is a case that is correctly called abnormal, and a “true positive” is a case that is correctly called normal. As used herein, “normalization” refers to the shifting and scaling of flow cytometry data (e.g., FCS parameter) per channel. While this use case is described with respect to data from Peripheral Blood (PB) samples and not bone marrow or other sample types, it should be understood that the developed predictive model can be used with other types of samples.

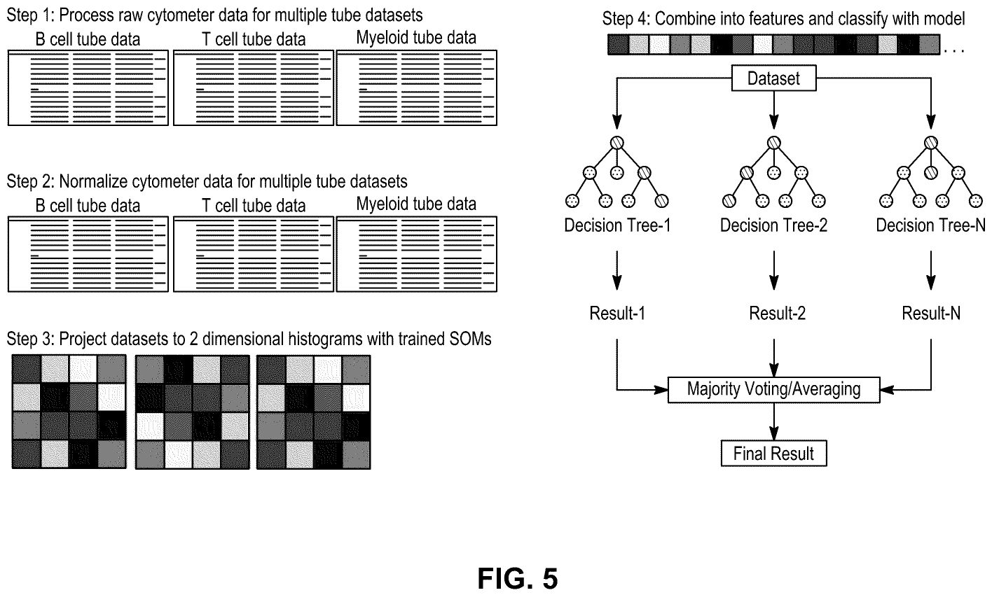

In this use case, the sample tube data is processed through one or more steps and data transfers as part of both training and inference. In some examples, processing of the flow cytometer data can be broken into four steps (see, e.g., FIG. 5). The first step includes of raw flow cytometer data processing, which generates sample files ready for analysis. The sample files (e.g., LMD files) may be generated by the cytometer instrument and transferred to a storage location (e.g., on-premises). This data transfer may be performed via a script installed on the cytometer instruction (i.e., the cytometer PC).

The second step includes data normalization in which the channel values for each sample are scaled relative to the statistical characteristics for each respective channel (e.g., derived from 50 recent samples). To perform this step, data is extracted from the sample files to generate CSV files and event data with cytometer output. The data normalization performed during this step may use, for example, multiple previously run samples as a source of normalization data.

The third step is a data reduction step that converts the scaled event data from a large collection (e.g., 13-parameter measurements with one 13 parameter measurement for each cell in a sample) into a smaller collection (e.g., a, 32×32, 2-dimensional (2D) grid of values). As described herein, this conversion can be performed using machine learning (ML) models called self-organizing maps (SOMs).

The fourth step includes application of an ML classifier model and a viability regressor model used in combination to infer if a sample is normal with high confidence. The output of this step may include the generation of a prediction, a viability estimate, and, optionally, other associated parameters (metadata), such as, for example, model version information for the ML model used to generate the prediction. This output may be stored in the database 140 and the stored data, or data generated based on the same, may be included in one or more reports (e.g., web-based report templates). It should be understood that the steps may be combined and distributed in various ways and additional steps may be included.

As illustrated in FIG. 5, in the first data processing step, data from raw data files for B-cell, T-cell, and myeloid flow cytometry tubes are extracted and compensated. The extracted data is saved as *.CSV files, each containing hundreds of thousands of 13-parameter flow cytometry events. Each event represents a single particle or cell for which 13 parameters were measured by the flow cytometer, including multiple scatter and fluorescence measurements. It should be understood that the number of parameters and events, as well as the type of file generated, during this step may vary based on, for example, clinical needs, samples processed, and instruments used.

Converted CSV data files are normalized before they are used in model training or inference. Each of the 13 sample parameters for B-cell, T-cell or myeloid tubes are corrected for parameter mean and standard deviation. To determine these corrections, the parameter means and standard deviations for a predetermined number (e.g., 50) of preceding (i.e., the most recent available) samples from the same cytometer are calculated. These parameter means and standard deviations are then combined over all the samples to determine medians for all 13 overall average parameter means and 13 overall parameter standard deviations. These values are used to normalize the current sample as follows:

$${p}_{c} ( i , n ) = \frac{p ( i , n ) - {μ}_{p sample} ( n )}{{σ}_{p sample} ( n )}$$

Where p_{c}(i, n) is the value of the nth parameter of the ith event in the corrected data file. Similarly, p(i, n) represents parameters in the uncorrected data file. Also, μ_{p sample}(n) represents the nth parameter median from the set of 50 high viability samples and σ_{p sample}(n) represents the nth parameter median of standard deviations from the set of samples.

For model training, the normalization process for a given sample includes identifying a predetermined number (e.g., 50) of the most proximate-in-time samples. For validation as well as production, an initial set of medians and mean standard deviations may be used to “prime” the process until the predetermined number of samples have been processed from which the parameter means and standard deviations can be generated. These predetermined number of sample results may be introduced into the database 140 before validation samples are run, where sample means and standard deviations for all tube parameters in the database 140.

In some examples, the SOMs 240 used in this use case include a 32×32 grid of points, often called centroids. Each centroid stores a location in 13-dimensional (13D) space, initially chosen randomly. During SOM training each of the (e.g., many millions) of the 13D data point measurements from a training set of flow cytometer data files (described below) is compared to all 13D locations stored in the SOM centroids. The 13D location of the centroid closest to the data point is shifted closer to the data points position and neighboring centroids' 13D positions are also shifted toward the data point but to a smaller degree. This is repeated until this process has been repeated for all training sample data points (events). This pass through all training data constitutes one training epoch and the training epoch may be repeated multiple times, such as for example, 30 times for each SOM. The result of SOM training is a centroid grid (e.g., a 32×32, 2D grid). The trained SOM centroid positions are used to project new data points from high dimensional space to 2D space. This is done by comparing the location of a data point in 13D with the locations in the trained SOM's centroids. The closest centroid will be the data point's new 2D position. With this method, all 13D data points are projected into one of the 32×32 grid locations. This SOM dimensionality reduction from 13D to 2D maintains relative clustering of data points from their original, high dimensional space to the 2D output and retains important relative information about datapoints in a less complex, smaller form. A separate SOM may be trained for the B-cell, T-cell, and myeloid tube data. Training data may be chosen from a data range that does not include any test or validation samples to exclude data used for result evaluation. Because SOM training is self-supervised, that is, no sample labels are needed, all samples from the training time ranges may be used regardless of label or sample type. In some examples, training data used to train the normal classifier and the viability regressor are first projected with the trained SOMs.

In some examples, the machine learning approach used to predict a sample's normal status includes the auto machine learning approach implemented in the open-source package Auto-Sklearn. This package automates and optimizes the machine learning steps of feature preprocessing, feature selection, model selection, hyperparameter tuning, and multi-model ensemble creation. The Auto-Sklearn package is closely tied to the Scikit-Learn package and pulls candidate models from Scikit-Learn. It should be understood, however, that other types of classifiers may be used with the systems and methods described herein. Training data taken from a chosen training time range may be initially projected using the trained SOM models described above. The SOM projected data for each training sample is then converted into a 32×32, 2D histogram representing the relative 2D distribution of a sample's hundreds of thousands of data points. This histogram is normalized such that all 32×32 histogram points sum to 1.0. These 1024 histogram points for each of the B-cell, T-cell, and myeloid tubes are then used as the input feature set for one training sample. The features and predetermined normal status labels for training samples are used as input to the Auto-Sklearn classifier trainer. Training consists of many attempted model pipelines that include feature preprocessing through model choice and hyperparameter tuning. The most successful models are retained and combined into the final ensemble model. Various training parameters may be set, such as setting a limit for full model training time, a parallel training limit, an individual model training time limit, and a maximum number of models in the final ensemble. Other training parameters could be used depending on resources, configurations, and data sizes.

In some examples, the same machine learning approach and package (e.g., Auto-Sklearn) may be used for the viability regressor as was used for the normal status classifier training described above. However, rather than classifying the normal status of a sample as normal or not normal, the regressor estimates a sample's cell viability along a continuous range. This regressor type model is a distinct regressor class within Auto-Sklearn, and inputs for the Auto-Sklearn regressor training included features for each training sample as described above for classifier training as well as manually determined sample viabilities. Again, various training parameters may be set, such as setting a limit for full model training time, a parallel training limit, an individual model training time limit, and a maximum number of models in the final ensemble. Other training parameters could be used depending on resources, configurations, and data sizes.

The ground truth labeling for the training data can include generating discrete, categorical data labels from raw report text in a two-step process. First, a natural language model specializing in biomedical tasks (e.g., BiomedBERT) can be used, wherein the natural language model was fine-tuned on a large corpus (approximately 25,000) of annotated report chart text to generate preliminary diagnosis labels for unreviewed chart text. Second, the cases are reviewed by residents, fellows, and/or medical directors to confirm or correct the preliminary model label. After a case is reviewed or if the prediction from the model for one or many of a set of possible diagnoses, including normal, is above a determined threshold, the case is marked as suitable for training, testing, and validation sets. These thresholds can be determined for each diagnosis such that predetermined percentage (e.g., 5%) of prediction scores for correct labels are below the threshold. A sample with multiple labels representing different diagnoses may only be included if all diagnoses are above the threshold, and a normal sample may only be included if no other diagnoses are above their respective thresholds (as in, the normal label must be mutually exclusive). This strategy leads to most normal and non-normal samples included in the training, testing, and validation sets for the respective time ranges and a small fraction of samples being rejected with lower-confidence labels.

Data processing for model inference may follow a similar process as described above and illustrated in FIG. 5. For example, interference may include a data reduction and feature preparation step, a model inference for normal status and viability step, and a final inference step. The data reduction and feature preparation step may include projecting events for each of the B-cell, T-cell, and myeloid tubes from their 13 parameters (seen as 13 dimensions) down to the 2D, 32×32 grid using the trained SOM models. The projected data is converted into the 32×32 normalized histograms for the B-cell, T-cell, and myeloid tubes as described in the normal classifier training section above. These reduced data histograms are then used as input features for the normal classifier and viability regressor machine learning models.

In the model inference for normal status and viability step, resulting SOM projection histograms for a case's B-cell, T-cell, and myeloid tube data are evaluated by two trained machine learning models. The first is a regression model, which estimates the viability of the sample. The second is a normal status classifier that generates a likelihood score between zero and one indicating the sample's status as normal or abnormal, hereafter referred to as positive or negative for normal. In some examples, both models are generated using the python package auto-sklearn described above in the model training subsections. In some examples, the classifier and regressor auto-sklearn models are not individual machine learning models, such as, for example, a random forest, but an ensemble of many models, typically having improved combined accuracy compared to a single model.

In the final inference step, the sample's inferred viability (determined in the previous step) is compared to a viability threshold. Likewise, the sample's normal status score is compared to a normal score threshold. In response to both values meeting or exceeding their respective thresholds, the sample is labeled positive as a highly confident normal, otherwise the sample is labeled negative.

For example, for each sample, the normal classification model generates a single score in the range [0.0,1.0], reflecting confidence that the sample is normal. To determine positive normal and not normal predictions, a threshold is established where higher thresholds yield higher specificity and precision (fewer false positive detections) but lower sensitivity. Because the threshold reflects business needs, it may be chosen manually by a user (e.g., medical directors and/or group managers after consulting a receiver operating characteristic (ROC) curve for the model). In some examples, the threshold for the normal classification model may be 0.910 but may vary based on clinical needs.

The viability regressor model may generate a single predicted viability in the range [0.0,100.0]. A high viability may be considered to be greater than or equal to 80%, but a cutoff may be established for the model to minimize the number of false high viability positives compared to the lab's prediction. For example, using a scatter plot showing the correlation of lab-derived versus regressor-predicted viability, a cutoff threshold for the predicted viability may be chosen manually using this ROC curve (e.g., plots showing the true positive rates (FPR) and false positive rates (TPR) of the model predictions that a sample's true viability is greater than or equal to 80% as the threshold for the model prediction is varied). In some examples, this threshold may be set at 85.5% but may vary based on clinical needs.

In production, the normal classifier model and the viability regressor may be used simultaneously. For a sample to be called normal, both the normal model score and the viability regressor prediction need to be at or above their respective thresholds. The final normal threshold will be reevaluated after filtering out low viability samples. These high viability normal cases will be considered positive normal cases and low viability normal cases will be considered negative normal cases for the remaining test cases.

For example, with the established thresholds, the models can be used to classify samples, such that a sample with a normal classifier score/prediction greater than the threshold X (e.g., 0.910) and a viability score/prediction greater than threshold Y (e.g., 85.5%) will be classified or called as normal, and a sample with a normal classifier score/prediction less than the threshold X or with a viability score/prediction less than threshold Y will be considered not normal. Similarly, a sample with a viability prediction greater than threshold Y and a classifier prediction greater than or equal to the threshold X will be identified as a true positive (TP) when the label was positive and a false positive (FP) when the label was negative. On the other hand, a sample with a viability prediction less the threshold Y and a classifier prediction less than the classifier X will be identified as a false negative (FN) when the label was positive and a true negative (TN) when the label was negative.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Various features, advantages, and examples are set forth in the following claims.

What is claimed is:

1. An apparatus for real-time data analytics comprising:
at least one electronic processor; and
at least one memory storing instructions executable by the at least one electronic processor, the at least one electronic processor configured, through execution of the instructions, to:
obtain flow cytometry data generated by a cytometry instrument representing cells of multiple categories;
generate a feature vector representation based on the flow cytometry data using a plurality of self-organizing maps (SOMs), wherein each SOM corresponds to a different category of multiple categories; and
predict each of one or more target labels of the cells by applying each of one or more regression models to the feature vector representation.

2. The apparatus of claim 1, wherein the at least one electronic processor is configured to generate the feature vector representation by:
generate a plurality of latent representations by applying each SOM to flow cytometry data representing cells of a corresponding category;
convert each of the plurality of latent representations into a one-dimensional vector representation to form a plurality of one-dimensional vector representations; and
concatenate the plurality of one-dimensional vector representations to generate the feature vector representation.

3. The apparatus of claim 1, wherein the one or more target labels is obtained from a dataset including clinically validated data, and the one or more regression models are trained on the clinically validated data.

4. The apparatus of claim 1, wherein the one or more regression models include at least one selected from a group consisting of a linear regressor and a random forest regressor.

5. The apparatus of claim 1, wherein the one or more target labels of the cells includes at least one selected from a group consisting of an absolute size, a fraction of cells, and a ratio between cell population sizes.

6. The apparatus of claim 1, wherein the flow cytometry data is Flow Cytometry Standard (FCS) data, and a category of the cells is a cell type.

7. The apparatus of claim 1, wherein the at least one electronic processor is further configured to:
update a dataset with the predicted one or more target labels of the cells, wherein the one or more target labels are obtained based on the dataset.

8. A computer-implemented method for analyzing flow cytometry data using machine learning comprising:
obtaining the flow cytometry data generated by a cytometry instrument representing cells of multiple categories;
generating a feature vector representation based on the flow cytometry data using a plurality of self-organizing maps (SOMs), wherein each SOM corresponds to a different category of the multiple categories; and
predicting, using a machine learning model, each of one or more target labels of the cells by applying each of one or more regression models to the feature vector representation.

9. The computer-implemented method of claim 8, wherein generating the feature vector representation comprises:
generating a plurality of latent representations by applying each SOM to flow cytometry data representing cells of a corresponding category;
converting each of the plurality of latent representations into a one-dimensional vector representation to form a plurality of one-dimensional vector representations; and
concatenating the plurality of one-dimensional vector representations to generate the feature vector representation.

10. The computer-implemented method of claim 8, wherein the one or more target labels are obtained from a dataset including clinically validated data, and the one or more regression models are trained on the clinically validated data.

11. The computer-implemented method of claim 8, wherein the one or more regression models include at least one selected from a group consisting of a linear regressor and a random forest regressor.

12. The computer-implemented method of claim 8, wherein the one or more target labels of the cells include at least one selected from a group consisting of an absolute size, a fraction of cells, and a ratio between cell population sizes.

13. The computer-implemented method of claim 8, wherein the flow cytometry data includes Flow Cytometry Standard (FCS) data, and each category of the multiple categories is a cell type.

14. The computer-implemented method of claim 8, further comprising:
updating a dataset with the predicted one or more target labels of the cells, wherein the one or more target labels are obtained based on the dataset.

15. A computer-implemented method for training a machine learning model, comprising:
obtaining flow cytometry data generated by a cytometry instrument representing cells of multiple categories using a data ingestion component;
generating a feature vector representation based on the flow cytometry data using a plurality of self-organizing maps (SOMs), wherein each SOM corresponds to a different category of the cells;
predicting a target label of one or more target labels of the cells by applying a regression model of one or more regression models to the feature vector representation;
computing a prediction loss based on difference between the predicted target label and ground truth data from a training dataset; and
updating parameters of the machine learning model based on the prediction loss.

16. The computer-implemented method of claim 15, wherein generating the feature vector representation further comprises:
generating a plurality of latent representations by applying each SOM to flow cytometry data representing cells of a corresponding category;
converting each of the plurality of latent representations into a one-dimensional vector representation to form a plurality of one-dimensional vector representations; and
concatenating the plurality of one-dimensional vector representations to generate the feature vector representation.

17. The method of claim 15, wherein the one or more regression models include at least one selected from a group consisting of a linear regressor and a random forest regressor.

18. The computer-implemented method of claim 15, wherein the one or more target labels of the cells include at least one selected from a group consisting of an absolute size, a fraction of cells, and a ratio between cell population sizes.

19. The computer-implemented method of claim 15, wherein the flow cytometry data is Flow Cytometry Standard (FCS) data, and a category of the cells is a cell type.

20. The computer-implemented method of claim 15, further comprising:
updating a training dataset with the predicted one or more target labels of the cells, wherein the one or more target labels are obtained based on the training dataset.
